(19) United States
(12) Patent Application Publication
(10) Pub. No.: US 2013/0308267 A1
(43) Pub. Date: Nov. 21, 2013

(54) SERVER ASSEMBLY

(71) Applicants: WEN-JEN WU, Tu-Cheng (TW); CHIH-WEI KAN, Tu-Cheng (TW)

(72) Inventors: WEN-JEN WU, Tu-Cheng (TW); CHIH-WEI KAN, Tu-Cheng (TW)

(73) Assignee: HON HAI PRECISION INDUSTRY CO., LTD., Tu-Cheng (TW)

(21) Appl. No.: 13/488,458

(22) Filed: Jun. 5, 2012

(30) Foreign Application Priority Data
May 15, 2012 (CN) 201210149634.4

(51) Int. Cl. H05K 7/20

(52) U.S. Cl. 361/679.53

(57) ABSTRACT

A rack includes a first pole, a second pole, a third pole, a fourth pole, four beams connected between the first to fourth poles, a number of first connection poles connected between the first pole and the second pole, and a number of second connection poles connected between the third pole and the fourth pole. The first to fourth poles, the beams, the first connection pole, and the second connection pole are all tubular and communicate with each other internally. A pump is arranged in a middle of each beam. Each first connection pole has a substantially same height with one of the second connection poles for sandwiching, together with the second connection pole, a liquid cooling server module which is operable to communicate with the rack internally to circulate cooling liquid.

### BACKGROUND

1. Technical Field

The present disclosure relates to a server assembly with a rack.

2. Description of Related Art

Servers generate a lot of heat in the housings of the servers during operation. A common method for dissipating the heat is to use fans. However, fans create noise and do not meet the ever-increasing need to dissipate heat.

### BRIEF DESCRIPTION OF THE DRAWINGS

Many aspects of the present embodiments can be better understood with reference to the following drawing. The components in the drawing are not necessarily drawn to scale, the emphasis instead being placed upon clearly illustrating the principles of the present embodiments. Moreover, in the drawing, like reference numerals designate corresponding parts throughout the several views.

FIG. 1 is an exploded, isometric view of a server assembly, according to an exemplary embodiment.

FIG. 2 is an assembled, side plan view of FIG. 1.

### DETAILED DESCRIPTION

The disclosure, including the accompanying drawing, is illustrated by way of examples and not by way of limitation. It should be noted that references to “an” or “one” embodiment in this disclosure are not necessarily to the same embodiment, and such references mean at least one.

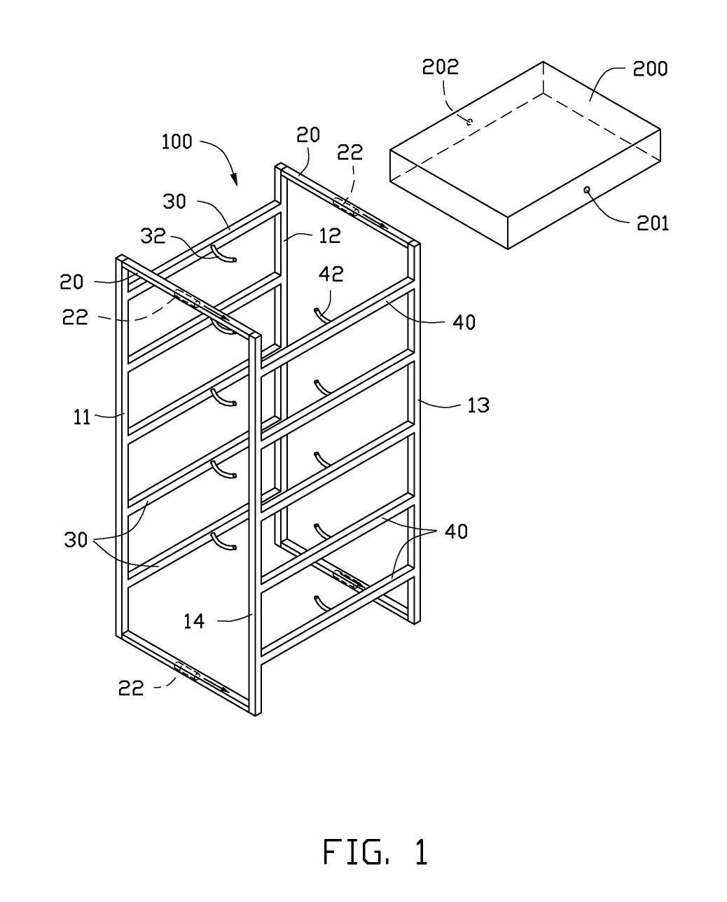

Referring to FIG. 1, an embodiment of a server assembly includes a rack 100, and a liquid-cooling server module 200 received in the rack 100.

The rack 100 is made of metal, and includes a first pole 11, a second pole 12, a third pole 13, a fourth pole 14, four beams 20, a plurality of first connection poles 30, and a plurality of second connection poles 40. Two of the beams 20 are connected between top ends and bottom ends of the first pole 11 and the fourth pole 14, respectively. The other two of the beams 20 are connected between top ends and bottom ends of the second pole 12 and the third pole 13, respectively. The first connection poles 30 are perpendicularly connected between the first pole 11 and the second pole 12. The second connection poles 40 are perpendicularly connected between the third pole 13 and the fourth pole 14. The first to fourth poles 11, 12, 13, 14, the beams 20, the first connection poles 30, and the second connection poles 40 are all tubular-shaped and communicate with each other.

A pump 22 is arranged in a middle of each beam 20. Each first connection pole 30 has a same height as one of the second connection poles 40, for sandwiching a liquid cooling server module 200 together with the second connection pole 40. The first connection poles 30 each have a flexible first pipe 32 communicating with the inner side of the first connection pole 30. The second connection poles 40 each have a flexible second pipe 42 communicating with the inside of the second connection pole 40.

The liquid cooling server module 200 utilizes cooling liquid, such as water or other liquid, to cool itself. The liquid cooling server module 200 defines an inlet 201 and an outlet 202 respectively in opposite sides of the server module 200.

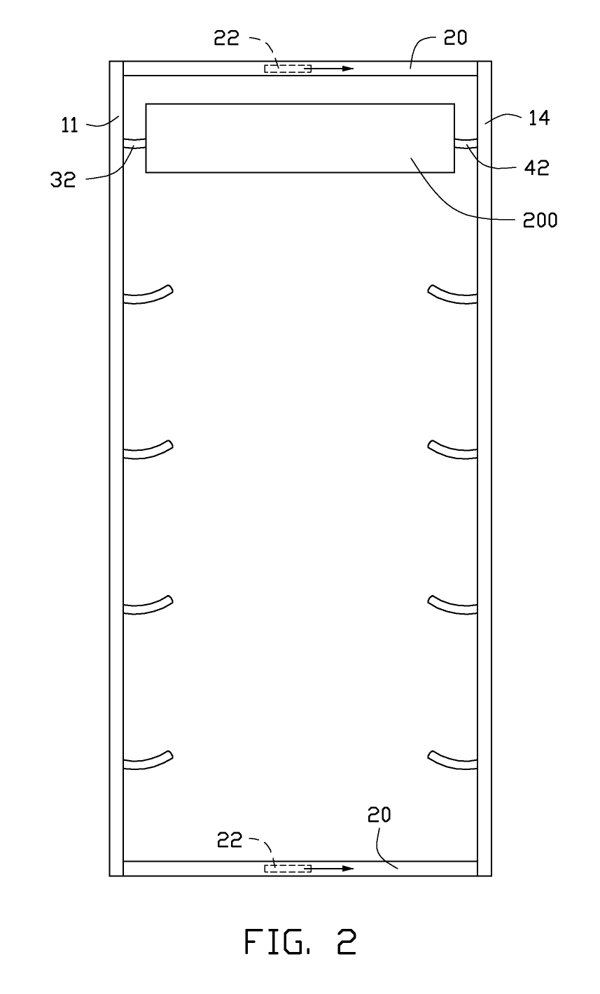

Referring to FIG. 2, the liquid cooling server module 200 is arranged between a first connection pole 30 and a corresponding second connection pole 40. The inlet 201 is connected to the second pipe 42. The outlet 202 is connected to the first pipe 32.

When the server module 200 operates, the cooling liquid in the liquid cooling server module 200 cools the server module 200, and then flows into the first connection pole 30 through the outlet 202 and the first pipe 32. The cooling liquid flows into the beams 20 through the first pole 11 and the second pole 12, and then flows into the second connection pole 40 through the third pole 13 and the fourth pole 14. The cooling liquid then flows into the server module 200 through the second pipe 42 and the inlet 201. The pumps 22 are used for supplying power for cycling the cooling liquid.

In the embodiment, the cooling liquid in the liquid cooling server module 200 is guided to the rack 100, to increase the area of the heat dissipation, thus dissipates heat effectively and reduce the quantity of fans.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A rack, comprising:
a first pole;
a second pole;
a third pole;
a fourth pole;
four beams, wherein two of the beams are connected between top ends and bottom ends of the first pole and the fourth pole, respectively; the other two of the beams are connected between top ends and bottom ends of the second pole and the third pole, respectively, a pump is arranged in a middle of each beam;
a plurality of first connection poles connected between the first pole and the second pole; and
a plurality of second connection poles connected between the third pole and the fourth pole;
wherein the first to fourth poles, the beams, the first connection poles, and the second connection poles are all tubular and communicate with each other internally, each first connection pole has a substantially same height with one of the second connection poles, for sandwiching, together with the second connection pole, a liquid cooling server module which is operable to communicate with the rack internally to circulate cooling liquid.

2. The rack of claim 1, wherein each of the first connection poles has a flexible first pipe communicating with inside of the first connection pole, each of the second connection poles has a flexible second pipe communicating with inside of the second connection pole.

3. A server assembly, comprising:
a server defining an inlet allowing cooling liquid to enter the server module, and an outlet allowing the cooling liquid to flow out of the server module; and
a rack comprising a first pole, a second pole, a third pole, a fourth pole, four beams a first connection pole connected between the first pole and the second pole, and a second connection pole connected between the third pole and the fourth pole; wherein two of the beams are connected between top ends and bottom ends of the first pole and the fourth pole, respectively; the other two of the beams are connected between top ends and bottom ends of the second pole and the third pole, respectively, a pump is arranged in a middle of each beam, wherein the first to fourth poles, the beams, the first connection pole, and the second connection pole are all tubular and communicate with each other internally, the first connection pole has a substantially same height with the second connection pole for sandwiching the server together with the second connection pole, the outlet is connected to the first connection pole, the inlet is connected to the second connection pole;
wherein when the server operates, the cooling liquid in the server cools the server, and then flows into the first connection pole through the outlet, the cooling liquid flows into the beams through the first pole and the second pole, and then flows into the second connection pole through the third pole and the fourth pole, the cooling liquid then flows into the server through the inlet, the pumps are operable for supplying power for cycling the cooling liquid.

4. The server assembly of claim 1, wherein a flexible first pipe is connected between the first connection pole and the outlet, a flexible second pipe is connected between the second connection pole and the inlet.
